(19) United States
(12) Patent Application Publication
(10) Pub. No.: US 2007/0194303 A1
(43) Pub. Date: Aug. 23, 2007

(54) Method for manufacturing organic light-emitting element, organic light-emitting device and organic EL panel

(76) Inventors: Gaku Harada, Osaka (JP); Tetsuji Omura, Gifu (JP)

Correspondence Address: MASUVALLEY & PARTNERS, 8765 AERO DRIVE, SUITE 312, SAN DIEGO, CA, 92123, US

(21) Appl. No.: 11/510,076

(22) Filed: Aug. 24, 2006

(30) Foreign Application Priority Data
Aug. 31, 2005 (JP) JP2005-252752

(51) Int. Cl. H01L 29/08; H01L 21/00

(52) U.S. Cl. 257/40; 438/82; 438/99

(57) ABSTRACT

In a method for manufacturing an organic light-emitting element, comprising holding an organic light-emitting element substrate with the use of an electrostatic chuck and bonding it to a sealing substrate, the present invention prevents a driving circuit incorporated in the organic light-emitting element substrate from deteriorating due to static electricity from the electrostatic chuck. In order to accomplish this, the present invention is characterized by providing on a second principal surface 1b of a substrate 1, or between a first principal surface 1a and the driving circuit 2 an electrically conductive layer 11 for preventing the driving circuit 2 from deteriorating due to the static electricity from the electrostatic chuck.

### TECHNICAL FIELD

The present invention relates to a method for manufacturing an organic electroluminescent (organic EL) element and an organic light-emitting element.

### BACKGROUND OF INVENTION

In recent years, an organic light-emitting element has been attracting attention as a self-luminous light-emitting element, and a display using the organic light-emitting element has been developed. The organic light-emitting element has features suitable for a motion image display, such as a high response speed, low voltage, and low power consumption, and therefore has been expected not only for an application to a next generation cellular phone or a personal digital assistant (PDA) but also as a next generation display.

An organic EL display comprises an organic EL panel having a plurality of pixels for an image display. A structure of an organic light-emitting element in the organic EL panel has a configuration in which an organic EL layer is sandwiched between two electrodes on a panel substrate. The organic EL layer is mainly comprised of an electron transport layer, a light-emitting layer, and a hole transport layer, and one of the two electrodes is an anode, and the other one is a cathode.

The organic EL display comprising such an organic EL panel is configured to emit light in such a way that applying positive and negative voltages to the anode and the cathode respectively causes holes injected from the anode to the organic EL layer and electrons injected from the cathode into the organic EL layer to reach the light-emitting layer through the hole transport layer and through the electron transport layer respectively, and the electrons and holes are recombined in the light-emitting layer to thereby emit light.

A conventional organic light-emitting element is sealed by bonding a capping glass plate or the like onto a substrate formed thereon with an organic EL film. The organic EL film is extremely vulnerable to moisture, and therefore the capping glass plate or the like coated with a drying agent is used.

Japanese published unexamined patent application No. H05-182759 has proposed a structure in which a sealing glass substrate is bonded with the use of a photocurable resin to thereby provide the sealing, instead of the sealing with a hollow structure configured by bonding the capping glass as described above. According to such a sealing procedure, a decrease in thickness can be provided because the procedure does not require the hollow structure, also there is no interference of light at interfaces between a cathode and air and between the air and the cap, and further a decrease in cost can be provided because the procedure does not require to use the drying agent.

However, there has arisen a problem that when the sealing glass substrate is bonded with the use of the photocurable resin as an adhesive, air bubbles intrude into an adhesive layer.

In order to solve such a problem, Japanese patent No. 3650101 has proposed a procedure in which a sealing substrate coated with an adhesive is bonded under a reduced pressure atmosphere. According to such a procedure, air bubbles arising at the time of the bonding under the reduced pressure atmosphere disappear if the sealing substrate is left in the air after the bonding, and therefore incorporation of the air bubbles into the adhesive layer can be prevented.

However, because the bonding is carried out under the reduced pressure atmosphere, a vacuum chuck cannot be used for holding a substrate. Also, in the case where the substrate is held with a mechanical chuck, because outer parts of the substrate are mechanically held with the use of clicks or a ring, a corresponding mechanism becomes complicated. Accordingly, if the substrate is held under the reduced pressure atmosphere, an electrostatic chuck should be used to thereby hold it. The present inventors have found that in the case where the substrate is held with the use of the electrostatic chuck, a problem of the change in characteristics of a thin film transistor that is a driving circuit in an organic light-emitting element arises.

Japanese published unexamined patent application No. 2003-271075 has proposed a structure in which the driving circuit is coated with an electrode layer through a dielectric layer in order to suppress the electrostatic breakage of the driving circuit. However, even in the case where such a structure was employed, the characteristics of the thin film transistor were changed, and uniformity on a light-emitting surface of the organic light-emitting element was reduced to thereby cause luminance unevenness.

It is therefore an object of the present invention to provide a method for manufacturing an organic light-emitting element and an organic light-emitting element that prevents the deterioration of a driving circuit incorporated in an organic light-emitting element substrate due to static electricity from an electrostatic chuck, comprising holding the organic light-emitting element substrate with the electrostatic chuck and bonding it to a sealing substrate.

### BRIEF SUMMARY OF THE INVENTION

The method for manufacturing an organic light-emitting element according to the present invention is characterized by comprising the steps of providing an active matrix driving circuit on a first principal surface of a substrate, providing thereon an organic light-emitting element structure, holding a second principal surface on a side opposite to the first principal surface with an electrostatic chuck in a reduced pressure chamber, the second principal surface including a sealing substrate, and pressing the organic light-emitting element substrate against the sealing substrate coated with an adhesive layer to thereby bond the sealing substrate onto the organic light-emitting element structure and thereby fabricating an organic light-emitting element substrate provided with an electrically conductive layer on the second principal surface of said substrate or between the first principal surface and the active matrix driving circuit.

Also, an insulation layer may be provided on the above electrically conductive layer. The electrically conductive layer is characterized by preventing the driving circuit from deteriorating due to static electricity from the electrostatic chuck.

That is, an insulation layer may be provided between the electrostatic chuck and the electrically conductive layer of the organic light-emitting element substrate, and providing such an insulation layer enables a short circuit caused by a contact between wiring and the electrically conductive layer to be prevented in the case where an insulation film covering the wiring comprising the electrostatic chuck is damaged and thereby the wiring is exposed.

Also, when the sealing substrate is bonded, the sealing substrate is held by a second electrostatic chuck, and a second electrically conductive layer for preventing the driving circuit of the organic light-emitting element substrate from deteriorating due to static electricity from the second electrostatic chuck may be provided on a side of the sealing substrate, the side being to be held by the second electrostatic chuck, or facing the organic light-emitting element substrate.

Further, a second insulation layer may be provided on the second electrically conductive layer.

In the present invention, the electrically conductive layer and/or the second electrically conductive layer may be formed from, for example, transparent conductive metal oxide. The transparent conductive metal oxide includes ITO (indium tin oxide), and indium zinc oxide (IZO). In the case of a top emission type organic light-emitting element, because light is taken out from the sealing substrate, the second electrically conductive layer provided on the sealing substrate is preferably formed from the transparent conductive metal oxide. On the other hand, in the case of a bottom emission type organic light-emitting element, because light is taken out from the substrate provided with the organic light-emitting element, the electrically conductive layer (first electrically conductive layer) provided on the organic light-emitting element substrate is preferably formed from the transparent conductive metal oxide.

Also, in the case where the second electrically conductive layer or the first electrically conductive layer is provided outside of the sealing substrate from which the light of the top emission type organic light-emitting element is taken out, or outside of the substrate from which the light of the bottom emission type organic light-emitting element is taken out, it may also be possible that a metal film having low transmittance is provided, and after the bonding of the substrates followed by curing of the adhesive, the electrically conductive layer is removed by a procedure such as etching or polishing.

In the case where the electrically conductive layer and/or the second electrically conductive layer are formed from the transparent conductive metal oxide, their thicknesses are preferable in the range of 10 to 1000 nm.

Also, the electrically conductive layer and/or the second electrically conductive layer in the present invention may be formed from a metal film. The metal film is not particularly limited, but may include, for example, a metal material used as an electrode in the organic light-emitting element, and aluminum, silver, molybdenum, or tungsten, or an alloy of them may be used.

In the case where translucency is required, each of them may be formed as a translucent metal thin film having reduced thickness. In such a case, a stacked structure with a transparent conductive metal oxide film may be employed.

In the case where the electrically conductive layer and the second electrically conductive layer are formed from a metal film, their thicknesses are preferably in the range of 100 to 1000 nm. In the case where they are formed as translucent metal films, their thicknesses are preferable in the range of 10 to 1000 nm.

In the present invention, in the case where the organic light-emitting element substrate or the sealing substrate is provided with color filter layers correspondingly to pixel regions of the organic light-emitting element substrate, and a black matrix is provided in a boundary region between the color filter layers, the black matrix may be formed from the electrically conductive layer or the second electrically conductive layer. In such a case, the electrically conductive layer and the second electrically conductive layer are preferably formed from a low reflective metal film. The low reflective metal film includes a metal film having a stacked structure of chromium and chromium oxide.

The organic light-emitting element of the present invention is characterized by being manufactured by any of the above methods according to the present invention.

Also, the organic light-emitting element according to the other aspect of the present invention, wherein an active matrix driving circuit is provided on a first principal surface of a substrate, an organic light-emitting element structure is provided thereon, and a sealing substrate is bonded thereonto through an adhesive layer, is characterized in that an electrically conductive layer is provided on a second principal surface on a side opposite to the first principal surface of the substrate, or between the first principal surface and the driving circuit.

In the organic light-emitting element of the present invention, an insulation layer may be provided on the electrically conductive layer.

Also, in the organic light-emitting element of the present invention, a second electrically conductive layer may be provided on a side of the sealing substrate, the side facing outward or facing the adhesive layer. Further, a second insulation layer may be provided on the second electrically conductive layer.

In the organic light-emitting element substrate of the present invention, an active matrix driving circuit for driving pixels each of which is comprised of organic layers is provided. Such a driving circuit includes a driving circuit employing thin film transistors (TFTs). Typically, onto such a driving circuit, an insulation film such as a planarizing film is provided, onto which the organic light-emitting element structure is formed. The organic light-emitting element structure of the present invention includes the following layer configurations:
(1) Anode/Organic EL light-emitting layer/Cathode,
(2) Anode/Hole injection layer/Organic EL light-emitting layer/Cathode,
(3) Anode/Organic EL light-emitting layer/Electron injection layer/Cathode,
(4) Anode/Hole injection layer/Organic EL light-emitting layer/Electron injection layer/Cathode,
(5) Anode/Hole injection layer/Hole transport layer/Organic EL light-emitting layer/Electron injection layer/Cathode, and
(6) Anode/Hole injection layer/Hole transport layer/Organic EL light-emitting layer/Electron transport layer/Electron injection layer/Cathode,

The above respective layers including the electrodes from the anode to the cathode are not particularly limited, but may employ any materials capable of comprising the organic light-emitting element, and for example, the organic light-emitting element may be comprised of materials having been conventionally used for an organic light-emitting element. Also, regarding a method for forming each of the layers, each of the layers can be formed by any of thin film forming methods including a vacuum evaporation method, a sputtering method, and a CVD method, depending on materials to be used.

Also, the anode may be on the substrate side and the cathode may be on the sealing substrate side, or alternatively the organic light-emitting element may be configured to have an inverted structure in which the cathode is on the substrate side and the anode is on the sealing substrate side.

Further, a passivation film may be formed on the organic light-emitting element structure. As the passivation film, any film functioning as a passivation layer of the organic light-emitting element can be used, and that having barrier properties against both moisture and lower molecular components is preferably used. Still further, in the case of the top emission structured organic light-emitting element, a material having high transparency in a visible light region (transmittance of 50% or more in the wavelength range of 400 to 800 nm) is preferably used. As such a material, inorganic oxide or inorganic nitride, such as SiOx, SiNx, SiNxOy, AlOx, TiOx, TaOx, or ZnOx, may be used. A method for forming the passivation film is not particularly limited unless it has an adverse effect on the organic light-emitting element, and the passivation film may be formed by a sputtering method, a CVD method, a vacuum evaporation method, a dipping method, or the like.

A thickness of the passivation film is preferably in the approximate range of 0.1 to 10 μm.

In the present invention, the organic light-emitting element substrate is held by the electrostatic chuck and pressed against the sealing substrate coated with the adhesive, and thereby the sealing substrate is bonded onto the organic light-emitting element structure through the adhesive layer.

As the adhesive in the present invention, the use of a fluid curable resin such as a photocurable resin or a heat curable resin is preferable. Curable types of resin include a UV curable type, a visible light curable type, a UV+heat curable type, a heat curable type, and a delayed curing UV adhesive. In the case where a substrate having a color filter or CCM (color conversion layer) is used for the sealing substrate, the heat curable type, the visible light curable type, the delayed curing UV adhesive, or the like is preferably used because ultraviolet light may not be able to transmit through the filter or the like.

Specific resins any of which may be used as the adhesive include: heat curable resin systems such as a urea resin system, melamine resin system, phenol resin system, resorcinol resin system, epoxy resin system, unsaturated polyester resin system, polyurethane resin system, and acrylic resin system; thermoplastic resin systems such as a polyvinyl acetate resin system, ethylene-vinyl acetate copolymer resin system, acrylic resin system, cyanoacrylate resin system, polyvinyl alcohol resin system, polyamide resin system, polyolefin resin system, heat curable polyurethane resin system, saturated polyester resin system, and cellulose type: radically photocurable type adhesives using resins such as various acrylates including ester acrylate, urethane acrylate, epoxy acrylate, melamine acrylate, and acrylic resin acrylate, and urethane polyester; cationic photocurable type adhesives using resins such as epoxy and vinyl ether; thiol-ene adduct type resin adhesives; rubber systems such as a chloroprene rubber system, nitrile rubber, styrene-butadiene rubber system, natural rubber system, butyl rubber system, and silicone system; and complex type synthetic polymer adhesives such as vinyl-phenolic, chloroprene-phenolic, nitrile-phenolic, nylon-phenolic, and epoxy-phenolic.

In the case of the top emission type organic light-emitting element, it is preferable to use an adhesive that becomes a colorless and transparent material with an average transmittance of 70% or more in the wavelength range of 450 to 800 nm after the curing.

The bonding of the organic light-emitting element substrate and the sealing substrate is carried out in such a way that in a state where the organic light-emitting element substrate is typically held with the electrostatic chuck, the organic light-emitting element substrate is aligned with the use of a CCD camera or the like, and then the organic light-emitting element substrate and the sealing substrate are relatively brought close to each other, pressed against each other, and bonded to each other. In this state, for example, an alignment is again carried out with the use of the CCD camera or the like and then the adhesive layer is cured. Temporarily curing may be carried out at the time, followed by another curing of the adhesive layer after the unload from the inside of the reduced pressure chamber. Depending on a type of the adhesive to be used, heat curing, photocuring such as UV curing, UV+heat curing, or the like is carried out.

According to the present invention, the deterioration of the driving circuit incorporated in the organic light-emitting element substrate due to the static electricity from the electrostatic chuck can be prevented in the method for manufacturing an organic light-emitting element, comprising holding the organic light-emitting element substrate with the electrostatic chuck and bonding it to the sealing substrate.

The organic light-emitting element according to the present invention can prevent the driving circuit incorporated in the organic light-emitting element substrate from deteriorating due to the static electricity from the electrostatic chuck in manufacturing process of the organic light-emitting element, comprising holding the organic light-emitting element substrate with the electrostatic chuck and bonding it to the sealing substrate.

### BRIEF DESCRIPTION OF THE DRAWINGS

FIG. 1 is a cross-sectional view illustrating a structure of an organic light-emitting element in any of Examples 1 to 3 according to the present invention.

FIG. 2 is a cross-sectional view illustrating a structure of an organic light-emitting element in any of Examples 4 to 9 according to the present invention.

FIG. 3 is a cross-sectional view illustrating a structure of an organic light-emitting element in Example 10 according to the present invention.

FIG. 4 is a cross-sectional view illustrating a structure of an organic light-emitting element in Example 11 according to the present invention.

FIG. 5 is a cross-sectional view illustrating a structure of an organic light-emitting element, which uses a black matrix as an electrically conductive layer similarly to Example 11, in an example according to the present invention.

FIG. 6 is a cross-sectional view illustrating a structure of an organic light-emitting element in Example 12 according to the present invention.

FIG. 7 is a cross-sectional view illustrating a structure of an organic light-emitting element in Example 13 according to the present invention.

FIG. 8 is a plan view illustrating a pattern of an electrically conductive layer in Example 1 according to the present invention.

FIG. 9 is a plan view illustrating a pattern of an electrically conductive layer in Example 2 according to the present invention.

FIG. 10 is a plan view illustrating a pattern of an electrically conductive layer in Example 3 according to the present invention.

FIG. 11 is a plan view illustrating a pattern of an electrically conductive layer in Example 4 according to the present invention.

FIG. 12 is a plan view illustrating a pattern of an electrically conductive layer in Example 5 according to the present invention.

FIG. 13 is a plan view illustrating a pattern of an electrically conductive layer in Example 6 according to the present invention.

FIG. 14 is a plan view illustrating a pattern of an electrically conductive layer in Example 7 according to the present invention.

FIG. 15 is a plan view illustrating a pattern of an electrically conductive layer in any of Examples 8 and 9 according to the present invention.

FIG. 16 is a cross-sectional view illustrating bonding apparatus used when the organic light-emitting element in any of Examples 1 to 9 according to the present invention is fabricated.

FIG. 17 is a cross-sectional view illustrating bonding apparatus used when the organic light-emitting element in any of Examples 10 to 14 according to the present invention is fabricated.

FIG. 18 is a cross-sectional view illustrating a holding state by an electrostatic chuck at the time when the organic light-emitting element in any of Examples 1 to 3 according to the present invention is fabricated.

FIG. 19 is a cross-sectional view illustrating a holding state by an electrostatic chuck at the time when the organic light-emitting element in any of Examples 4 to 9 according to the present invention is fabricated.

FIG. 20 is a cross-sectional view illustrating a holding state by an electrostatic chuck at the time when the organic light-emitting element in Example 10 according to the present invention is fabricated.

FIG. 21 is a cross-sectional view illustrating a holding state by an electrostatic chuck at the time when the organic light-emitting element in Example 12 according to the present invention is fabricated.

FIG. 22 is a cross-sectional view illustrating a holding state by an electrostatic chuck at the time when the organic light-emitting element in Example 13 according to the present invention is fabricated.

FIG. 23 is a diagram illustrating a voltage shift amount (ΔV) in a V-I characteristic curve of a TFT.

FIG. 24 is a diagram illustrating a relationship between applied voltage at the time of the holding by the electrostatic chuck and the voltage shift amount in each of the examples and comparative examples.

FIG. 25 is a top view illustrating a state where a video signal driving circuit and a vertical scanning signal driving circuit are connected to any of the above-described organic light-emitting elements.

### DETAILED DESCRIPTION OF INVENTION

The present invention will hereinafter be more specifically described in reference to examples; however, the present invention is not limited to the following examples.

### EXAMPLES 1 TO 3

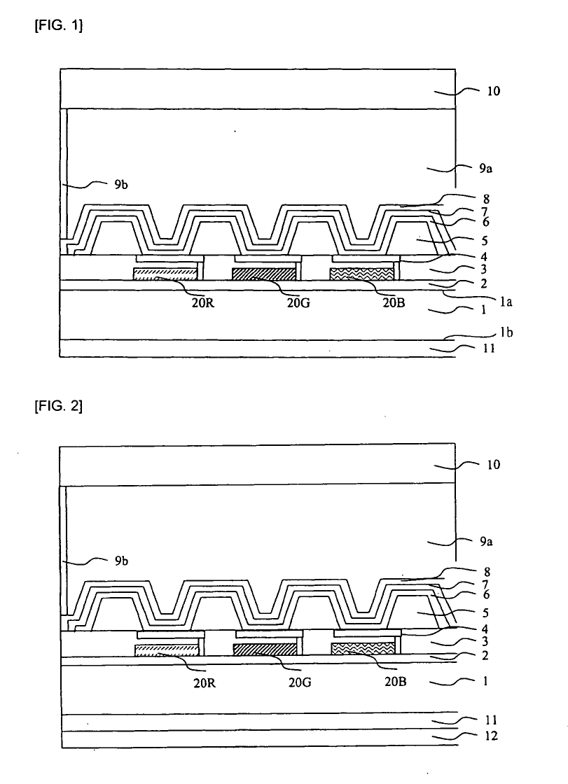

An organic light-emitting element shown in FIG. 1 was fabricated. As shown in a cross-sectional view of FIG. 1, a first principal surface 1a of a substrate 1 comprised of a glass substrate is formed thereon with a polysilicon type TFT circuit 2 including a gate electrode. A second principal surface 1b on a side opposite to the first principal surface 1a is formed thereon with an electrically conductive layer 11. The electrically conductive layer 11 is formed from ITO, which is a transparent conductive film, and has a thickness of 100 nm. The electrically conductive layer 11 is formed by a sputtering method.

A red color filter 20R, a green color filter 20G, and a blue color filter 20 B are provided on the TFT circuit 2 correspondingly to respective pixel regions. On the TFT circuit 2, an insulation film 3 made of SiO₂ is formed. The insulation film 3 is formed thereon with anodes 4 (thickness of 100 nm) made of ITO, correspondingly to the respective pixel regions. The anodes 4 are connected to electrodes of the TFT circuit 2 via throughholes in the insulation layer 3.

Pixel isolation films 5 are formed between pixels in the respective pixel regions on the insulation film 3. The pixel isolation films 5 are formed from PMMA (polymethyl methacrylate). Each of the pixel isolation films 5 is formed only in a region between the pixels on the anodes 4, which is a non-pixel region.

A hole injection layer is formed over the entire region so as to cover the anodes 4 and the pixel isolation films 5. The hole injection layer is comprised of, for example, carbon fluoride (CFx) with a thickness of 1 nm.

Onto the hole injection layer, a hole transport layer and an orange light-emitting layer are sequentially formed. The hole transport layer is formed from, for example, a triarylamine derivative, and is here comprised of NPB (N,N′-Di(naphthalene-1-yl)-N,N′-diphenyl-benzidine) with a thickness of 60 nm expressed by Formula (1).

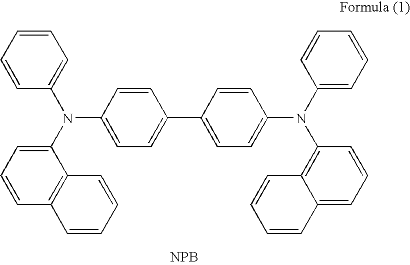

The orange light-emitting layer has a configuration in which a host material is doped with a first dopant and a second dopant. In addition, the orange light-emitting layer has a thickness of, for example, 30 nm.

As the host material of the orange light-emitting layer, for example, NPB same as the material for the hole transport layer may be used.

As the first dopant of the orange light-emitting layer, for example, tBuDPN (5,12-Bis(4-tert-butylphenyl)naphthacene) expressed by Formula (2) may be used. The first dopant is doped into the orange light-emitting layer so as to be contained in an amount of 20 wt. %.

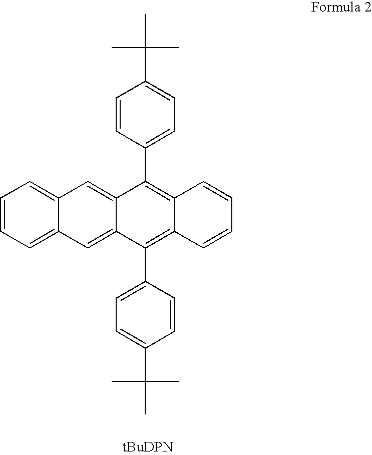

As the second dopant of the orange light-emitting layer, for example, DBzR (5,12-bis(4-(6-methylbenzothiazol-2-yl)phenyl)-6,11-diphenylnaphthacene) expressed by Formula (3) may be used. The second dopant is doped into the orange light-emitting layer so as to be contained in an amount of 3 wt. %.

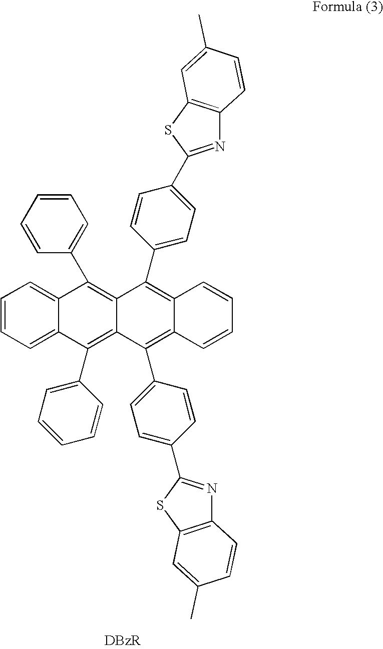

The second dopant of the orange light-emitting layer emits light, and the first dopant functions to assist in the light emission of the second dopant by facilitating energy transfer from the host material to the second dopant because the first dopant has intermediate values between values of the host material and the second dopant in terms of both a highest occupied molecular orbital (HOMO) level and a lowest unoccupied molecular orbital (LUMO) level. This causes the orange light-emitting layer to emit orange light having a peak wavelength more than 500 nm and less than 650 nm.

Subsequently, a blue light-emitting layer is formed onto the orange light-emitting layer. The blue light-emitting layer has a configuration in which a host material is doped with a first dopant and a second dopant. In addition, the blue light-emitting layer has a thickness of, for example, 40 nm.

As the host material of the blue light-emitting layer, for example, TBADN (2-tert Butyl-9,10-di(2-naphthyl)anthracene) expressed by Formula (4) may be used.

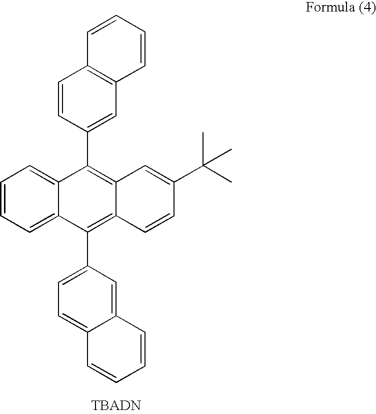

As the first dopant of the blue light-emitting layer, for example, NPB same as the material for the hole transport layer may be used. The first dopant is doped into the blue light-emitting layer so as to be contained in an amount of 10 wt. %.

As the second dopant of the blue light-emitting layer, for example, TBP (1,4,7,10-Tetra-tert butyl perylene) expressed by Formula (5) may be used. The second dopant is doped into the blue light-emitting layer so as to be contained in an amount of 2.5 wt. %.

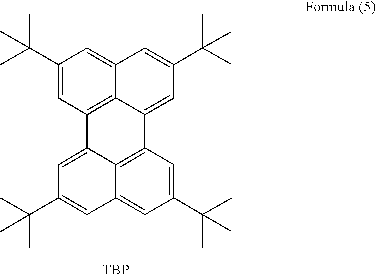

The second dopant of the blue light-emitting layer emits light, and the first dopant is made of a hole transport material and functions to assist in the light emission of the second dopant by facilitating transport of holes to thereby facilitate recombination of carriers in the blue light-emitting layer. This causes the blue light-emitting layer to emit blue light having a peak wavelength more than 400 nm and less than 500 nm.

Subsequently, an electron transport layer 6, an electron injection layer 8, and a cathode 7 are formed onto the blue light-emitting layer.

The electron transport layer is comprised of, for example, Alq3 (Tris (8-hydroxyquinolinato) aluminum) with a thickness of 10 nm expressed by Formula (6).

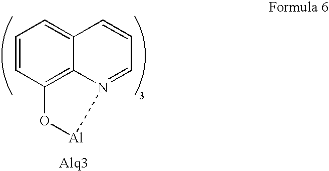

The electron injection layer is comprised of, for example, lithium fluoride (LiF) with a thickness of 1 nm, and the cathode 7 is comprised of, for example, aluminum (Al) with a thickness of 200 nm. Onto the cathode 7, a passivation film 8 made of SiNx is formed.

Onto an organic light-emitting element substrate fabricated in a manner as described, a sealing substrate 10 comprised of a glass substrate is bonded through an adhesive layer 9a. In a peripheral part of the adhesive layer 9a, an adhesive layer 9b is formed in a direction perpendicular to the substrate surface.

In the above examples, a white light-emitting element is configured, in which the orange light-emitting layer and the blue light-emitting layer are stacked, and the color filters are provided correspondingly to the respective pixel regions; however, an organic light-emitting element may be configured by a separate coating procedure in which a red light-emitting layer, a green light-emitting layer and a blue light-emitting layer are provided correspondingly to each R pixel, each G pixel, and each B pixel. Alternatively, in the organic light-emitting element by the separate coating procedure, color filters may be provided correspondingly to respective pixels.

The above-described bonding of the organic light-emitting element substrate and the sealing substrate was carried out with the use of bonding apparatus shown in FIG. 16. The bonding apparatus shown in FIG. 16 is configured to become a reduced-pressure chamber by the combination of an upper chamber 16 and a lower chamber 17. The upper chamber 16 is attached with an upper substrate-holding plate 14, and the upper substrate-holding plate 14 is attached with an electrostatic chuck 13. The lower chamber 17 is attached with a lower substrate-holding plate 15. The upper substrate-holding plate 14 holds the organic light-emitting element substrate with the use of the electrostatic chuck 13. The lower substrate-holding plate 15 is a mechanical chuck, which directly holds the sealing substrate.

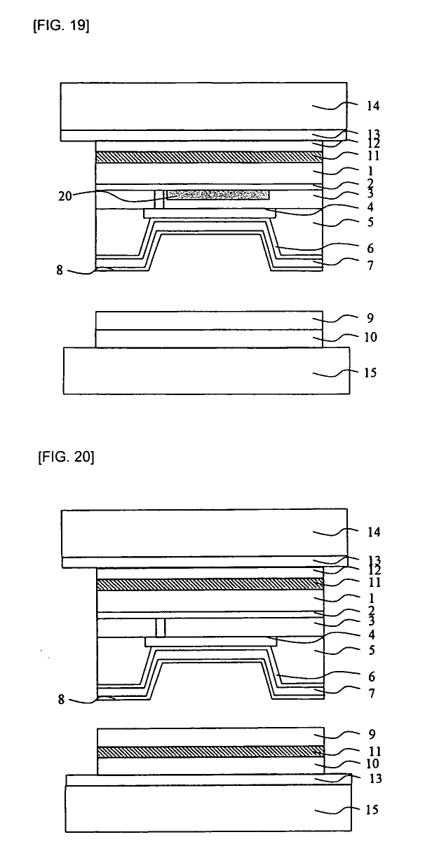

FIG. 18 is a cross-sectional view for describing a step of bonding the organic light-emitting element substrate and the sealing substrate in the examples shown in FIG. 1 with the use of the bonding apparatus shown in FIG. 16. In addition, FIG. 18 shows only one pixel of the organic light-emitting element substrate. Each of FIGS. 19 to 22 also shows only one pixel similarly to FIG. 18.

As shown in FIG. 18, the substrate 1 of the organic light-emitting element substrate is held by the electrostatic chuck 13 through the electrically conductive layer 11. The sealing substrate 10 is held by the lower substrate-holding plate 15 under the condition that it is coated thereon with an adhesive layer 9 and the adhesive layer 9 faces upward. The sealing substrate 10 was cleaned on its surface by a UV ozone treatment, followed by being coated thereon with an adhesive in a predetermined pattern by the use of a printing method such as screen printing, or with the use of a dispenser. In addition, the cleaning of the sealing substrate and the coating of the adhesive were carried out under a dry nitrogen atmosphere. As the adhesive 9a, a UV curable epoxy resin (trade name of “TB3112” manufactured by Three Bond Co., Ltd.) was used. As the adhesive 9b used for the peripheral part, the above UV curable epoxy resin added with SiOx in an amount of 10 wt. % as a filler to be thereby thickened was used.

The organic light-emitting element substrate and the sealing substrate are set into the apparatus in a state where they are held in a manner as described, then the upper chamber 16 and the lower chamber 17 are closed to seal an inside of the chamber, and further an exhaust valve is opened to depressurize the inside of the chamber to a pressure of 1 to 10 Pa. A position of the organic light-emitting element substrate is aligned with the use of a CCD camera, and then the upper substrate-holding plate 14 is lowered to bond the organic light-emitting element substrate to the sealing substrate. The position was again aligned with the use of the CCD camera, and then the adhesive 9 was irradiated with ultraviolet light with the use of an UV lamp to be thereby temporarily cured. Upon completion of the bonding, the vacuum inside of the chamber was broken, then chamber was opened, and the bonded substrates were unloaded and irradiated again with the ultraviolet light with the use of the UV lamp under a dry atmosphere to thereby completely cure the adhesive layer.

In the vacuum processing by which the above organic light-emitting element structure is formed, the organic light-emitting element substrate is mechanically held. Therefore, the deterioration of the TFT circuit due to static electricity arising as it arises when the substrate is held with an electrostatic chuck does not arise. Also, when the above-described organic layers are formed, evaporation sources are located below, and therefore the organic light-emitting element substrate is arranged such that the first principal surface of it faces downward. The electrostatic chuck is configured to be attached to the upper substrate-holding plate of the bonding apparatus and adapted to hold the organic light-emitting element substrate so that the organic light-emitting element substrate can be directly set into the bonding apparatus without being inverted after the fabrication of the substrate.

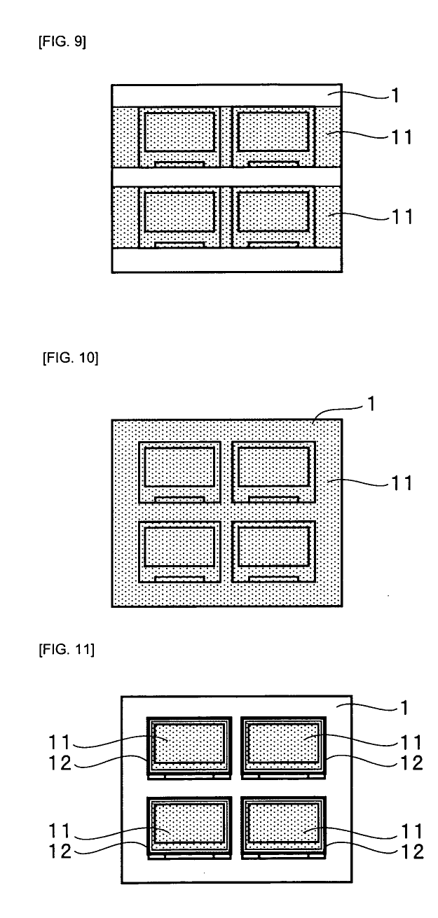

FIG. 8 is a plan view illustrating a pattern of the electrically conductive layer 11 in Example 1. In addition, FIG. 8 shows pixel parts and TFT circuit parts so that positions at which the electrically conductive layer 11 is formed can easily be grasped. This pattern is practically formed on the other side of the substrate and therefore corresponds to a part one cannot see. Also in FIGS. 9 to 15, a situation is the same as above.

As shown in FIG. 8, in Example 1, the electrically conductive layer 11 is formed on a region that covers a pixel part in each of the pixel regions and a corresponding peripheral driving circuit.

FIG. 9 is a plan view illustrating a pattern of the electrically conductive layer 11 in Example 2. As shown in FIG. 9, in Example 2, the electrically conductive layer 11 is formed in a pattern extending in a transverse direction so as to cover a pixel in each of the pixel regions and a corresponding peripheral driving part.

FIG. 10 is a plan view illustrating a pattern of the electrically conductive layer 11 in Example 3. As shown in FIG. 10, in Example 3, the electrically conductive layer 11 is formed so as to cover the entire back surface of the substrate 1.

### EXAMPLES 4 TO 8

An organic light-emitting element shown in a cross-sectional view of FIG. 2 was fabricated. As shown in FIG. 2, in these examples, an insulation layer 12 is formed onto an electrically conductive layer 11. As the electrically conductive layer 11, an ITO film with a thickness of 100 nm was formed by a sputtering method, similarly to Examples 1 to 3. The insulation layer 12 was formed from a SiN film (thickness of 500 nm) by a CVD method.

FIG. 11 is a plan view illustrating patterns of the electrically conductive layer 11 and the insulation layer 12 in Example 4. Regions of the electrically conductive layer 11 are represented by dots, similarly to FIGS. 8 to 10. Regarding the insulation layer 12, corresponding regions are represented by bold lines. In Example 4, the electrically conductive layer 11 and the insulation layer 12 are respectively formed so as to cover pixel parts and corresponding peripheral driving circuits as shown in FIG. 11.

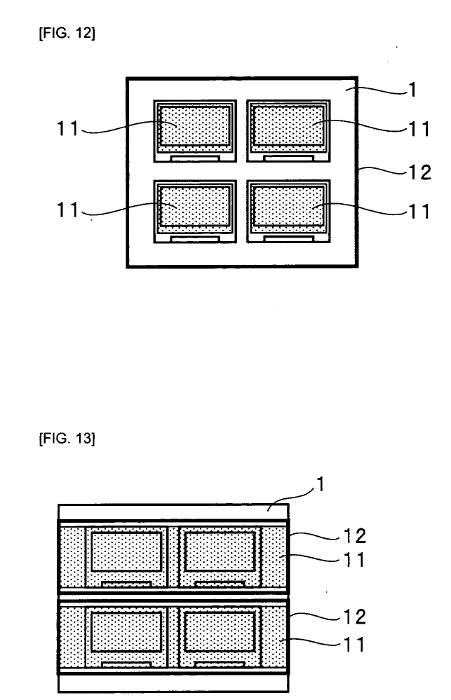

FIG. 12 is a plan view illustrating patterns of the electrically conductive layer 11 and the insulation layer 12 in Example 5. As shown in FIG. 12, in Example 5, the electrically conductive layer 11 is formed so as to cover pixel parts and corresponding peripheral driving circuits, similarly to Example 4, and the insulation layer 12 is formed so as to cover the entire surface of the substrate 1.

FIG. 13 is a plan view illustrating patterns of the electrically conductive layer 11 and the insulation layer 12 in Example 6. As shown in FIG. 13, in Example 6, the electrically conductive layer 11 is formed so as to extend in a transverse direction, similarly to the electrically conductive layer 11 shown in FIG. 9, and the insulation layer is also similarly formed so as to extend in a transverse direction.

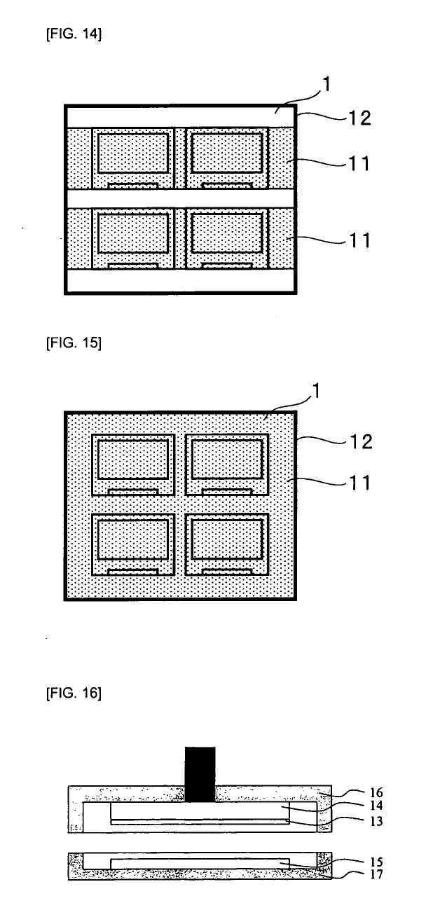

FIG. 14 is a diagram illustrating patterns of the electrically conductive layer 11 and the insulation layer 12 in Example 7. As shown in FIG. 14, the electrically conductive layer 11 in Example 7 is formed so as to extend in a transverse direction, similarly to Example 6, and the insulation layer 12 is formed on the entire second principal surface of the substrate 1.

FIG. 15 is a plan view illustrating patterns of the electrically conductive layer 11 and the insulation layer 12 in Example 8. As shown in FIG. 15, in Example 8, the electrically conductive layer 11 and the insulation layer 12 are formed so as to cover the entire second principal surface of the substrate 1.

In each of Examples 4 to 8, an organic light-emitting element substrate and a sealing substrate were bonded to each other with the use of the bonding apparatus shown in FIG. 16, similarly to Examples 1 to 3.

### EXAMPLE 9

In this example, an organic light-emitting element was fabricated in a manner similar to Example 8, except that an electrically conductive layer 11 was formed with the use of aluminum that has higher conductivity than ITO, instead of the use of ITO. Accordingly, patterns of the electrically conductive layer 11 and an insulation layer 12 are same as those shown in FIG. 15. In addition, the electrically conductive layer 11 made of aluminum was formed by a vacuum evaporation method so as to have a thickness of 100 nm.

Because this example is a bottom emission type light-emitting element, and if the electrically conductive layer 11 made of aluminum is provided, light emitted in an organic layer becomes difficult to transmit outside from the substrate 1, the electrically conductive layer 11 and the insulation layer 12 on the substrate 1 are eliminated by polishing after bonding of an organic light-emitting element substrate and a sealing substrate.

The electrically conductive layer 11 of the present invention may also be formed by the attachment of metal foil such as aluminum foil. In the case of metal foil having adhesiveness such as adhesive tape, it can easily be removed after the bonding of the organic light-emitting element substrate and the sealing substrate.

### EXAMPLES 10 TO 13

The above-described Examples 1 to 9 are related to bottom emission type organic light-emitting elements; however, in Examples 10 to 13, top emission type organic light-emitting elements were fabricated.

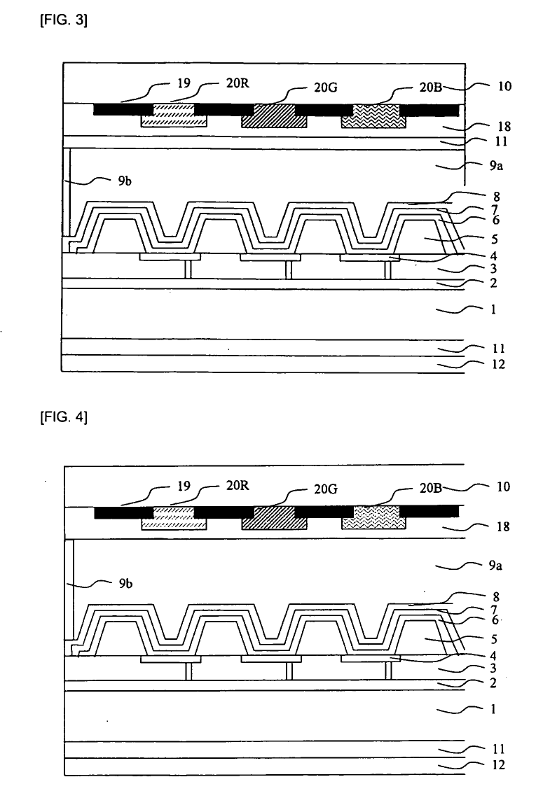

FIG. 3 is a cross-sectional view illustrating an organic light-emitting element in Example 10. An organic light-emitting element substrate similar to that in Example 9 was fabricated, except for color filters not provided on a TFT circuit 2, and an electrode material. Because of the similarity to Example 9, an electrically conductive layer 11 (thickness of 100 nm) made of aluminum and an insulation layer 12 (thickness of 500 nm) made of SiN are formed onto a second principal surface 1b of a substrate 1. In addition, an anode in this example has a structure in which an aluminum film and an ITO film are stacked, each of which has a thickness of 100 nm. Also, a cathode is formed from a stacked structure of Li (thickness of 1 nm)/Ag (thickness of 10 nm)/IZO (thickness of 100 nm).

Also, a red color filter 20R, a green color filter 20G, and a blue color filter 20B are provided on a sealing substrate 10, correspondingly to respective pixel regions, and a black matrix 19 made of resin is provided between the respective filters.

Further, an overcoat 18 made of acrylic resin is provided so as to cover the black matrix 19 and the respective color filters.

As described later, in this example, a sealing substrate 10 is held by an electrostatic chuck, and therefore a second electrically conductive layer 11 is provided on a side facing the sealing substrate 10. In this example, the second electrically conductive layer 11 is formed on the overcoat 18. The second electrically conductive layer 11 is made of ITO, and has a thickness of 100 nm.

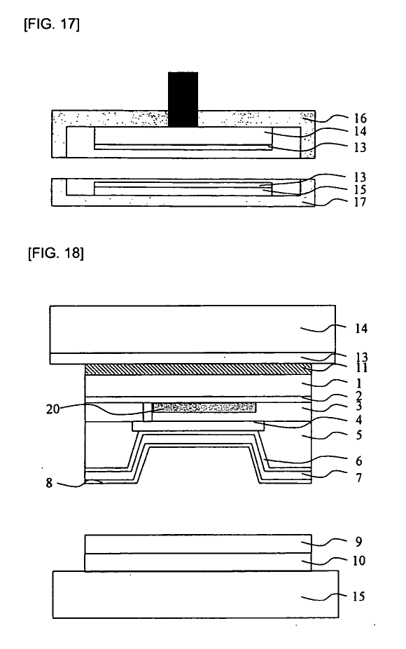

In this example, the organic light-emitting element substrate and the sealing substrate were bonded to each other with the use of bonding apparatus shown in FIG. 17. The bonding apparatus shown in FIG. 17 is configured to hold both of the organic light-emitting element substrate and the sealing substrate with electrostatic chucks. Accordingly, an electrostatic chuck 13 is provided also on a lower substrate-holding plate 15.

FIG. 20 is a cross-sectional view illustrating a state where the organic light-emitting element substrate and the sealing substrate in Example 10 are about to be bonded to each other with the use of the bonding apparatus shown in FIG. 17. As shown in FIG. 20, the organic light-emitting element substrate is held by the upper electrostatic chuck 13 through the electrically conductive layer 11 and the insulation layer 12. Also, the sealing substrate 10 is held by the lower electrostatic chuck 13. Because the second electrically conductive layer 11 is provided on the sealing substrate 10, deterioration of the TFT circuit 2 due to static electricity from the lower electrostatic chuck 13 can be prevented by the second electrically conductive layer 11. Also, the deterioration due to static electricity from the upper electrostatic chuck 13 can be prevented by the electrically conductive layer 11 provided on the substrate 1.

FIG. 4 is a cross-sectional view illustrating an organic light-emitting element in Example 11. In Example 11, a black matrix made of low reflective metal having a stacked structure of chromium and chromium oxide is used, instead of the use of the black matrix made of resin. The black matrix 19 is used as a second electrically conductive layer in the present invention. That is, in this example, the black matrix 19 made of metal and functioning as the second electrically conductive layer is provided on a sealing substrate 10. Because it is a black matrix, it is not formed in pixel regions, and therefore a state where any electrically conductive layer is not present in pixel openings is configured. Accordingly, the second electrically conductive layer is provided only in regions where no pixel is present, i.e., nondisplay parts.

Also in the case of Example 11 shown in FIG. 4, an organic light-emitting element substrate and the sealing substrate can be bonded to each other with the use of the bonding apparatus shown in FIG. 17 in a manner similar to the above-described Example 10.

FIG. 5 is a cross-sectional view illustrating an example using a metallic black matrix having a stacked structure of chromium and chromium oxide, similarly to Example 11, in a bottom emission type organic light-emitting element. In this example, an electrically conductive layer 11 and an insulation layer 12 are provided also outside of a substrate 1.

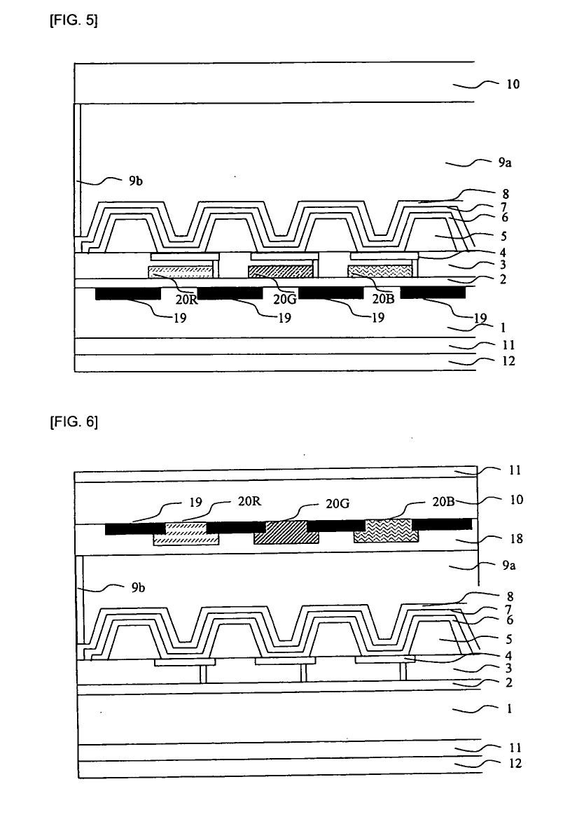

FIG. 6 is a cross-sectional view illustrating an organic light-emitting element in Example 12. In Example 12, a second electrically conductive layer 11 is provided on an upper surface of a sealing substrate 10, i.e., on a holding side to be held with an electrostatic chuck. Except for this point, this example is similar to Example 10 shown in FIG. 3.

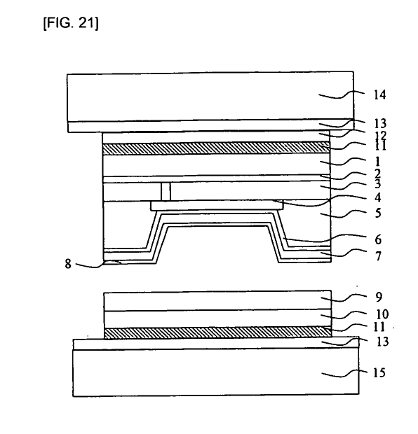

FIG. 21 is a cross-sectional view illustrating a state where an organic light-emitting element substrate and the sealing substrate in Example 12 are about to be bonded to each other with the use of the bonding apparatus shown in FIG. 17. As shown in FIG. 21, the lower electrostatic chuck 13 holds the sealing substrate 10 through the second electrically conductive layer 11, and deterioration of an TFT circuit 2 due to static electricity from the lower electrostatic chuck 13 is prevented by the second electrically conductive layer 11.

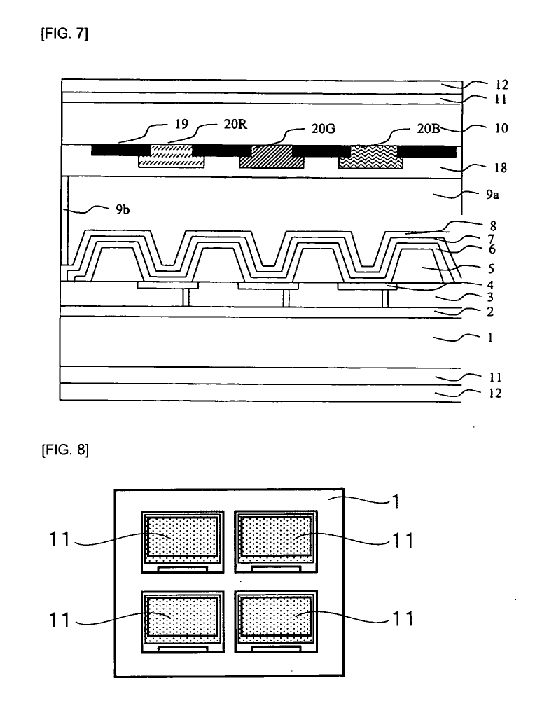

FIG. 7 is a cross-sectional view illustrating an organic light-emitting element in Example 13. As shown in FIG. 7, this example is similar to Example 12, except that a second insulation layer 12 is formed on a second electrically conductive layer 11 provided on a holding side of a sealing substrate 10. The second insulation layer 12 is formed from SiN by a CVD method, and has a thickness of 500 nm.

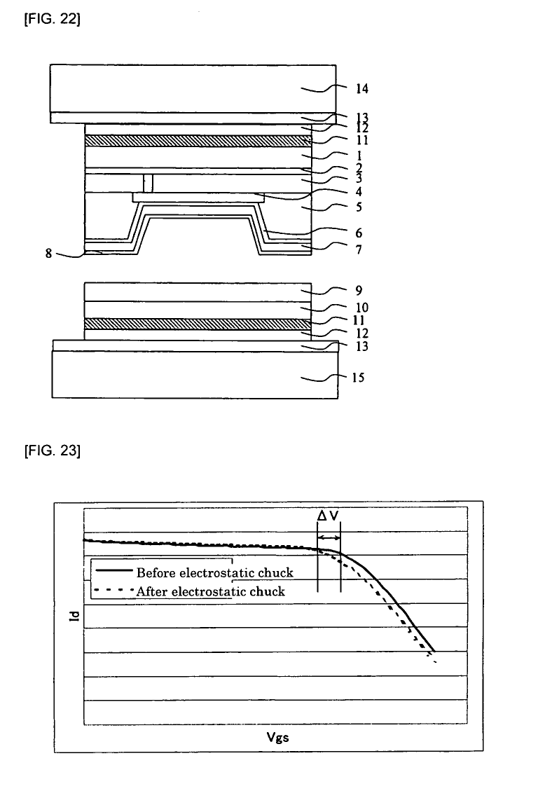

FIG. 22 is a cross-sectional view illustrating a state where an organic light-emitting element substrate and the sealing substrate in Example 13 shown in FIG. 7 are about to be bonded to each other with the use of the bonding apparatus shown in FIG. 17. As shown in FIG. 22, the sealing substrate 10 is held by a lower electrostatic chuck 13 through the second electrically conductive layer 11 and the second insulation layer 12.

Deterioration due to static electricity from an upper electrostatic chuck 13 is prevented by an electrically conductive layer 11 on a substrate 1, and that from the lower electrostatic chuck 13 is prevented by the second electrically conductive layer 11 provided on the sealing substrate 10.

In addition, the second electrically conductive layer and the second insulation layer on the sealing substrate side in each of Examples 10 to 13 are provided on the entire surface of the sealing substrate.

### EXAMPLE 14

In this example, an organic light-emitting element was fabricated in a manner similar to Example 10, except that the second electrically conductive layer 11 on the sealing substrate 10 side in Example 10 was not provided. Therefore, it was fabricated under the influence of static electricity from a lower electrostatic chuck.

### COMPARATIVE EXAMPLE 1

In Comparative Example 1, an organic light-emitting element was fabricated in a manner similar to Example 1, except that an electrically conductive layer 11 was not formed.

### COMPARATIVE EXAMPLE 2

An organic light-emitting element was fabricated in a manner similar to Comparative Example 1, except that a thickness of substrate glass of an organic light-emitting element substrate was doubled from 0.7 mm in the above Comparative Example 1 to 1.4 mm.

Structures of the organic light-emitting elements in Examples 1 to 14 and Comparative Examples 1 and 2 fabricated as above are summarized in Table 1. Also, specific configurations of structures 1 to 5 shown in Table 1 are shown in Table 2. In addition, in Tables 1 and 2, the organic light-emitting element substrate is indicated as “a TFT substrate”.

TABLE 1

| | | TFT substrate side | | Sealing substrate side | |
|---|---|---|---|---|---|
| | | | Electrically | | Electrically |
| | | | conductive layer/ | | conductive |
| | | Pattern | Insulation layer | Pattern | layer |
| Example 1 | Structure 1 | Pixel parts | ITO | None | None |
| Example 2 | | Transverse | ITO | None | None |
| | | pattern | | | |
| Example 3 | | Entire surface | ITO | None | None |
| Example 4 | Structure 2 | Pixel parts/ | ITO/SiN | None | None |
| | | Pixel parts | | | |
| Example 5 | | Pixel parts/ | ITO/SiN | None | None |
| | | Entire surface | | | |
| Example 6 | | Transverse | ITO/SiN | None | None |
| | | pattern/ | | | |
| | | Transverse | | | |
| | | pattern | | | |
| Example 7 | | Transverse | ITO/SiN | None | None |
| | | pattern/Entire | | | |
| | | surface | | | |
| Example 8 | | Entire surface/ | ITO/SiN | None | None |
| | | Entire surface | | | |
| Example 9 | | Entire surface/ | Al/SiN | None | None |
| | | Entire surface | | | |
| Example 10 | Structure 3 | Entire surface/ | Al/SiN | Entire surface | ITO |
| | | Entire surface | | (Adhesive side) | |
| Example 11 | | Entire surface/ | Al/SiN | Light-emitting | ITO |
| | | Entire surface | | parts are open | |
| | | | | (Adhesive side) | |
| Example 12 | Structure 4 | Entire surface/ | Al/SiN | Entire surface | ITO |
| | | Entire surface | | | |
| Example 13 | Structure 5 | Entire surface/ | Al/SiN | Entire surface | ITO/SiN |
| | | Entire surface | | | |
| Example 14 | Structure 2 | Entire surface/ | Al/SiN | None | None |
| | | Entire surface | | | |
| Comparative | — | None | None | None | None |
| Example 1 | | | | | |
| Comparative | — | None | Glass | None | None |
| Example 2 | | | | | |

TABLE 2

| | TFT substrate side | Sealing substrate side |
|---|---|---|
| Structure 1 | TFT substrate/Electrically | None |
| | conductive layer | |
| Structure 2 | TFT substrate/Electrically | None |
| | conductive layer/Insulation | |
| | layer | |
| Structure 3 | TFT substrate/Electrically | Sealing substrate/Electrically |
| | conductive layer/Insulation | conductive layer/Adhesive |
| | layer | |
| Structure 4 | TFT substrate/Electrically | Electrically conductive layer/ |
| | conductive layer/Insulation | Sealing substrate/Adhesive |
| | layer | |
| Structure 5 | TFT substrate/Electrically | Insulation layer/Electrically |
| | conductive layer/Insulation | conductive layer/Sealing |
| | layer | substrate/Adhesive |

Evaluation of TFT characteristics

A voltage shift amount (ΔV) between a gate and a source of each of the organic light-emitting elements fabricated in Examples 1 to 14 and Comparative Examples 1 and 2 was measured. Specifically, TFT characteristics of the TFT circuit were preliminarily measured in the form of the organic light-emitting element substrate, and the measurement result was compared with TFT characteristics after the fabrication of the organic light-emitting element by the bonding of the sealing substrate with the use of the electrostatic chuck.

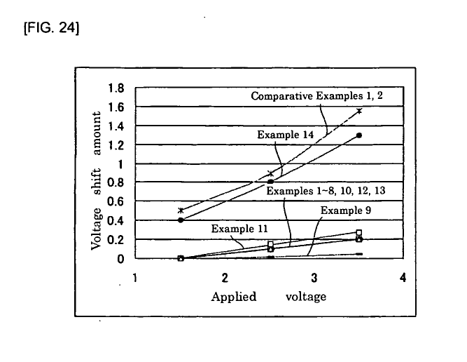

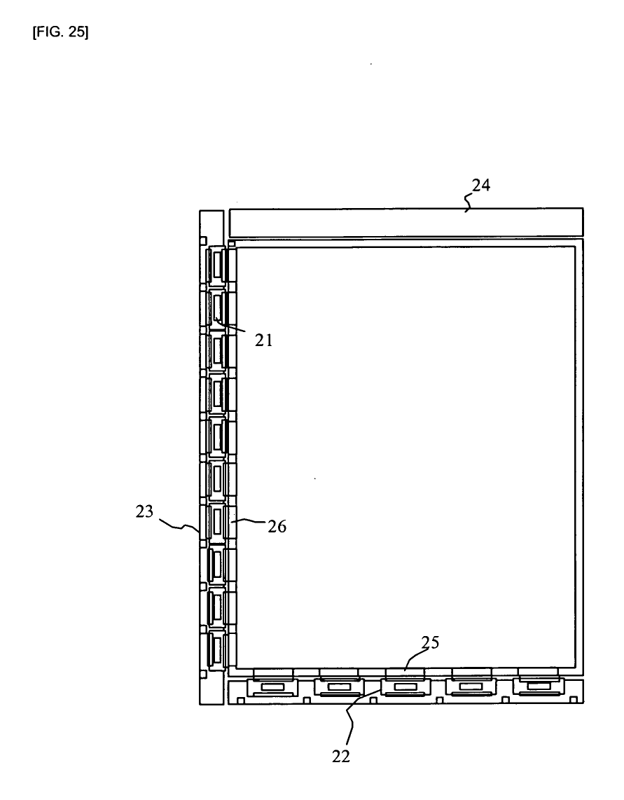

FIG. 23 is a diagram for describing an evaluation procedure used at the time. As shown in FIG. 23, a variation amount between threshold voltages before and after the holding with the electrostatic chuck was obtained as the voltage shift amount ΔV. In addition, in each of the examples and comparative examples, a voltage applied to the electrostatic chuck at the time of the holding with the electrostatic chuck was varied from 1.5 kV, to 2.5 kV to 3.5 kV, i.e., three different types of organic light-emitting elements were fabricated in each example, and a relationship between the applied voltage at the time and the voltage shift amount was shown in FIG. 24.

As is clear from FIG. 24, in each of Examples 1 to 8, the voltage shift amount was, for example, 0.2 V at 3.5 kV. In Example 9, because aluminum having higher conductivity was used as the electrically conductive layer, the voltage shift amount was 0.05 V at 3.5 kV, which was smaller than those in Examples 1 to 8.

In each of Examples 10 to 13, aluminum was also used as the electrically conductive layer located on the organic light-emitting element substrate side; however, because the second electrically conductive layer located on the sealing substrate side was formed from ITO, the voltage shift amount was comparable to those in Examples 1 to 8.

In Example 14, it is reasonable that the voltage shift amount is larger in comparison with those in the other examples because the second electrically conductive layer is not provided on the sealing substrate side. In each of Comparative Examples 1 and 2, it is also reasonable that the voltage shift amount is larger in comparison with those in Examples 1 to 14 because no electrically conductive layer is provided.

FIG. 25 is a top view illustrating a state where a video signal driving circuit and a vertical scanning signal driving circuit are connected to any of the above-described organic light-emitting elements.

Specifically, a driving IC chip 21 is comprised of each video signal driving IC chip and each vertical scanning signal driving IC chip both for driving an organic EL panel. Five IC chips 21 mounted on driving circuit boards 22 on a lower side of FIG. 25 are the driving IC chips for the vertical scanning signal, and 10 IC chips 21 mounted on driving circuit boards 23 on the left-hand side are the driving IC chips for the video signal. The driving circuit boards 22 and 23 are in the form of a tape carrier package on which the driving IC chips 21 are mounted by a Tape Automated Bonding (TAB) method, and divided into two portions for the video signal driving circuit and the scanning signal driving circuit as shown in FIG. 25.

The video signal and the vertical scanning signal are applied to the above-described organic light-emitting element at predetermined timings by the respective IC chips mounted on these driving circuit boards 22 and 23 to thereby generate an image to be displayed on each organic light-emitting element. A power supply circuit 24 supplies driving voltage.

In addition, regarding groups of terminals, respective scanning circuit connecting terminals 25, video signal circuit connecting terminals 26 and their corresponding lead-out wiring parts are integrated into a plurality of the groups on a unit basis of a tape carrier package (TCP) onto which the integrated circuit chips 21 are mounted. Lead-out wirings from a matrix part to an external connecting terminal part in each of the groups are inclined toward both ends. This is intended to conform the terminals 25 and 26 of the organic EL panel to an array pitch of the package TCP and connecting terminal pitches of the respective driving circuit boards 22 and 23.

This organic EL panel is assembled in such a way that the lower substrate-holding plate 15 and the upper substrate-holding plate 14 are overlapped with each other and sealed, and then the upper and lower substrates are cut off. In manufacturing processing of the organic EL panel of the present invention, in the case of a small panel size, a plurality of devices are simultaneously processed with one glass substrate and then divided in order to improve throughput whereas in the case of a large panel size, a glass substrate having a standardized size is processed for any of panel types into that having a small size suitable to each of the panel types in order to share manufacturing equipment, and in either case, upon completion of a series of process steps, the glass is cut off.

It turns out from the above that providing the electrically conductive layer for preventing the deterioration due to static electricity from the electrostatic chuck according to the present invention enables the deterioration of the TFT circuit to be prevented in process of the fabrication of the organic light-emitting element held by the electrostatic chuck.

In addition, the present invention is not limited to the above examples, but may be variously altered in terms of a constitution of the invention, and in claim construction, claims should be most widely construed.

What is claimed is:

1. A method for manufacturing an organic light-emitting element, comprising the steps of:
providing an active matrix driving circuit on a first principal surface of a substrate;
providing thereon an organic light-emitting element structure;
holding a second principal surface on a side opposite to the first principal surface with an electrostatic chuck in a reduced pressure chamber, the second principal surface including a sealing substrate; and
pressing the organic light-emitting element substrate against the sealing substrate coated with an adhesive layer to thereby bond the sealing substrate onto the organic light-emitting element structure;
thereby fabricating an organic light-emitting element substrate provided with an electrically conductive layer on the second principal surface of said substrate or between the first principal surface and the active matrix driving circuit.

2. The method for manufacturing an organic light-emitting element according to claim 1, wherein an insulation layer is provided on the electrically conductive layer.

3. The method for manufacturing an organic light-emitting element according to claim 1, wherein the electrically conductive layer prevents the driving circuit from deteriorating due to static electricity from the electrostatic chuck.

4. The method for manufacturing an organic light-emitting element according to claim 3, wherein when the sealing substrate is bonded, the sealing substrate is held by a second electrostatic chuck, and a second electrically conductive layer for preventing the driving circuit of the organic light-emitting element substrate from deteriorating due to static electricity from the second electrostatic chuck is provided on a side of the sealing substrate, wherein the side is the side held by the second electrostatic chuck, or the side is the side facing the organic light-emitting element substrate.

5. The method for manufacturing an organic light-emitting element according to claim 4, wherein a second insulation layer is provided on the second electrically conductive layer.

6. The method for manufacturing an organic light-emitting element according to claim 5, wherein both the electrically conductive layer and the second electrically conductive layer are formed from transparent conductive metal oxide or one of the electrically conductive layer and the second electrically conductive layer are formed from transparent conductive metal oxide.

7. The method for manufacturing an organic light-emitting element according to claim 6, wherein both the electrically conductive layer and the second electrically conductive layer are formed from a metal film or one of the electrically conductive layer and the second electrically conductive layer are formed from a metal film.

8. The method for manufacturing an organic light-emitting element according to claim 7, wherein the metal film is a low-reflective metal film.

9. The method for manufacturing an organic light-emitting element according to claim 7, further comprising:
the step wherein the organic light-emitting element substrate or the sealing substrate is provided with color filter layers correspondingly to pixel regions of the organic light-emitting element substrate; and
the step wherein a black matrix is provided in a boundary region between the color filter layers,
wherein the black matrix is formed from the electrically conductive layer or the second electrically conductive layer.

10. The method for manufacturing an organic light-emitting element according to claim 1,
where both the electrically conductive layer and the second electrically conductive layer are formed on the second principal surface of the organic light-emitting element substrate and on the side to be held of the sealing substrate,
the method further comprising the step of removing the electrically conductive layer and the second electrically conductive layer after the step of bonding the sealing substrate onto the organic light-emitting element structure.

11. The method for manufacturing an organic light-emitting element according to claim 1,
where either the electrically conductive layer or the second electrically conductive layer are formed on the second principal surface of the organic light-emitting element substrate or on the side to be held of the sealing substrate,
the method further comprising the step of removing the electrically conductive layer or the second electrically conductive layer after the step of bonding the sealing substrate onto the organic light-emitting element structure.

12. The method for manufacturing an organic light-emitting element according to claim 10,
where both the insulation layer and the second insulation layer are provided on the electrically conductive layer and the second electrically conductive layer,
the method further comprising the step of removing the insulation layer and the second insulation layer along with the electrically conductive layer and the second electrically conductive layer.

13. The method for manufacturing an organic light-emitting element according to claim 10,
where either the insulation layer or the second insulation layer are provided on the electrically conductive layer or the second electrically conductive layer,
the method further comprising the step of removing the insulation layer or the second insulation layer along with the electrically conductive layer or the second electrically conductive layer.

14. An organic light-emitting element fabricated by the method according to any one of claims 1.

15. An organic light-emitting element wherein an active matrix driving circuit is provided on a first principal surface of a substrate, an organic light-emitting element structure is provided thereon, and a sealing substrate is bonded-thereon through an adhesive layer,
wherein an electrically conductive layer is provided on a second principal surface on a side opposite to the first principal surface of the substrate, or between the first principal surface and the driving circuit.

16. The organic light-emitting element according to claim, 15, wherein an insulation layer is provided on the electrically conductive layer.

17. The organic light-emitting element according to claim, 15, wherein a second electrically conductive layer is provided on a side of the sealing substrate, wherein the side of the sealing substrate is either the side facing outward or the side facing the adhesive layer.

18. The organic light-emitting element according to claim, 17, wherein a second insulation layer is provided on the second electrically conductive layer.

19. An organic EL panel comprising the organic light-emitting element according to claim 15, wherein the active matrix driving circuit is comprised of a video signal driving circuit and a vertical scanning signal driving circuit, and a video signal is applied to the organic light-emitting element through the video signal driving circuit and a vertical scanning signal is applied to the organic light-emitting element at a predetermined timing to thereby generate an image to be displayed on each organic light-emitting element.
